(19) United States
(12) Patent Application Publication
(10) Pub. No.: US 2026/0173334 A1
(43) Pub. Date: Jun. 18, 2026

(54) COOLING SYSTEM FOR POWER SEMICONDUCTOR MODULES

(71) Applicant: ZF Friedrichshafen AG, Friedrichshafen (DE)

(72) Inventors: Venkataramana Prasad Amasbyl, Friedrichshafen (DE); Udayrao Cheeti, Friedrichshafen (DE); Christoph Schikora, Regensburg (DE); Pranesh Kumar Chandramohan, Friedrichshafen (DE)

(73) Assignee: ZF Friedrichshafen AG, Friedrichshafen (DE)

(21) Appl. No.: 19/422,098

(22) Filed: Dec. 16, 2025

(30) Foreign Application Priority Data
Dec. 16, 2024 (DE) 10 2024 211 954.7

(51) Int. Cl. H05K 7/20

(52) U.S. Cl. CPC H05K 7/209

(57) ABSTRACT

A cooling assembly for power semiconductor modules has a substrate and at least one power semiconductor module attached to the substrate, wherein the power semiconductor modules have at least one semiconductor switch and are encased in an insulating compound, aside from at the electrical connections, signal connections, and a cooling connection on the bottom of the power semiconductor module, and the cooling connection forms a cooling structure extending from the bottom of the power semiconductor module, and the substrate has a cutout where the at least one power semiconductor module is attached, such that the cooling structure extends from the top of the substrate, where the power semiconductor module is, to the bottom.

### CROSS-REFERENCE TO RELATED APPLICATION

This application claims priority to German Patent Application No. 10 2024 211 954.7 filed on Dec. 16, 2024, the entirety of which is hereby fully incorporated by reference herein.

### TECHNICAL FIELD

The present disclosure relates to the field of electric mobility, specifically electronic modules for an electric drive.

### BACKGROUND

The use of electronic modules, also referred to as power electronics, in motor vehicles has increased significantly in the last decade. This is because of the necessity of fuel conservation and improving vehicle performance, and because of the advances in semiconductor technology. The main components therein are an electronic control unit (ECU), which is connected to vehicle control units, or is a part thereof, and receives control signals and/or data based on driving behavior or signals from other control units, and a DC/AC inverter that supplies alternating current to electric machines such as motors or generators. A direct current generated by a DC energy source such as a battery, is converted into multi-phase alternating current for this. The inverter has numerous electronic components, in particular semiconductor switches, with which bridge circuits (half bridges) are obtained. The semiconductor switches are either individual topological switches or have already been connected to a half bridge and are surrounded by an electrically insulating compound. In this configuration, they are also referred to as power semiconductor modules. Only their electrical and signa/control contacts, and a cooling connection are not encased in the insulating compound.

The semiconductor switches in the power semiconductor module must be actively cooled to discharge heat from switching and conductance losses. A thermal conductance path from the power semiconductor module through an insulating and thermal conducting element in the form of a direct bonded copper (DBC) printed circuit board, and a support structure, are created in a coolant.

### SUMMARY

One goal is to make electronic modules lighter and less expensive, without impacting the performance of the power semiconductor module.

This is solved by the features disclosed herein. Advantageous embodiments are also the subject matter of the present disclosure.

A cooling assembly for power semiconductor modules is created that has a substrate and at least one power semiconductor module attached thereto, in which the power semiconductor modules have at least one semiconductor switch and are encased in an insulating compound, aside from at the electrical connections, signal connections, and a cooling connection on the bottom of the power semiconductor module, and in which the cooling connection forms a cooling structure that extends from the bottom of the power semiconductor, and in which the substrate is cut out where the at least one power semiconductor module is attached such that the cooling structure extends from the top of the substrate where the power semiconductor module is located, to the the bottom of the substrate.

In one embodiment, the insulating compound forms a collar where it encompasses the cooling structure, extending from the bottom of the power semiconductor module, with which it is attached to the substrate.

In one embodiment, the top of the substrate has a recess for the collar.

In one embodiment, adhesive is placed in the recess to secure the collar therein, which also forms a seal. A seal can also be placed in the recess, in which case a clamp is placed on the top of the power semiconductor module that presses the power semiconductor module against the seal.

The cooling structure for the power semiconductor module can be formed by fins or pins.

There can be a structure on the bottom of the substrate that corresponds to the cooling structure for the power semiconductor module, which holds it in place there.

The substrate can be made of metal or plastic.

A power electronics module is also obtained for operating a three-phase electric motor in a vehicle in which the power electronics contains an inverter formed by at least one power semiconductor module, the cooling assembly described above, and at least one electronic control unit that is connected to the electric motor and the inverter.

A power semiconductor module is also obtained that has at least one semiconductor switch, which is encased in an insulating compound, aside from at the electrical connections, signal connections, and a cooling connection on the bottom of the power semiconductor module, in which the cooling connection forms a cooling structure extending from the bottom of the power semiconductor module.

The insulating compound forms a collar extending from the bottom of the power semiconductor module where it surrounds the cooling structure.

Other features and advantages of the present disclosure can be derived from the following descriptions of exemplary embodiments of the invention, the drawings showing details of the present disclosure, and the claims. The individual features can be implemented in and of themselves, or in numerous arbitrary combinations with which variations of the present disclosure are obtained.

Preferred embodiments of the present disclosure shall be explained in greater detail below in reference to the drawings.

### BRIEF DESCRIPTION OF THE DRAWINGS

FIG. 1 shows a substrate populated by numerous power semiconductor modules according to the prior art from above;

FIG. 2 shows the assembly in FIG. 1 from below;

FIG. 3 shows the substrate in FIG. 1 without power semiconductor modules from above:

FIG. 4 shows an embodiment of a power semiconductor module according to the present disclosure from below;

FIG. 5 shows an embodiment of a substrate according to the present disclosure from below;

FIG. 6 shows an embodiment of a substrate populated with power semiconductor modules according to the present disclosure from below;

FIG. 7 shows an embodiment of a substrate according to the present disclosure from above;

FIG. 8 shows an embodiment of a substrate populated with power semiconductor modules according to the present disclosure from above; and

FIG. 9 shows a sectional view of an embodiment of a substrate populated with power semiconductor modules according to the present disclosure.

### DETAILED DESCRIPTION

Identical elements and functions have the same reference symbols in the following descriptions of the drawings.

As stated above, the semiconductor switches for operating an inverter in a power semiconductor module 1 must be actively cooled in order to discharge the heat from switching and conductance losses occurring during the operation thereof. There is a thermal conductance path from the semiconductor switch to a coolant that has a very low thermal resistance. For this, a printed circuit board comprising a copper layer, ceramic layer and subsequent copper layer, is normally connected to the bottom of the semiconductor switch. The lowest copper layer forms a (thermally conductive) cooling connection to a substrate 2 (or base plate). This printed circuit board can be a direct bonded copper (DBC) or active metal brazed (AMB) element. The power semiconductor module 1 and substrate 2 thus form a cooling assembly with which the power semiconductor modules 1 populating the substrate are cooled. The power semiconductor module 1, composed of the semiconductor switch and printed circuit board is encased in an electrically insulating layer 12, a so-called mold. Only the electrical connections 10 and signal connections 11 that come in contact with the semiconductor switch, and the lower copper layer, are not encased in the insulating layer 12.

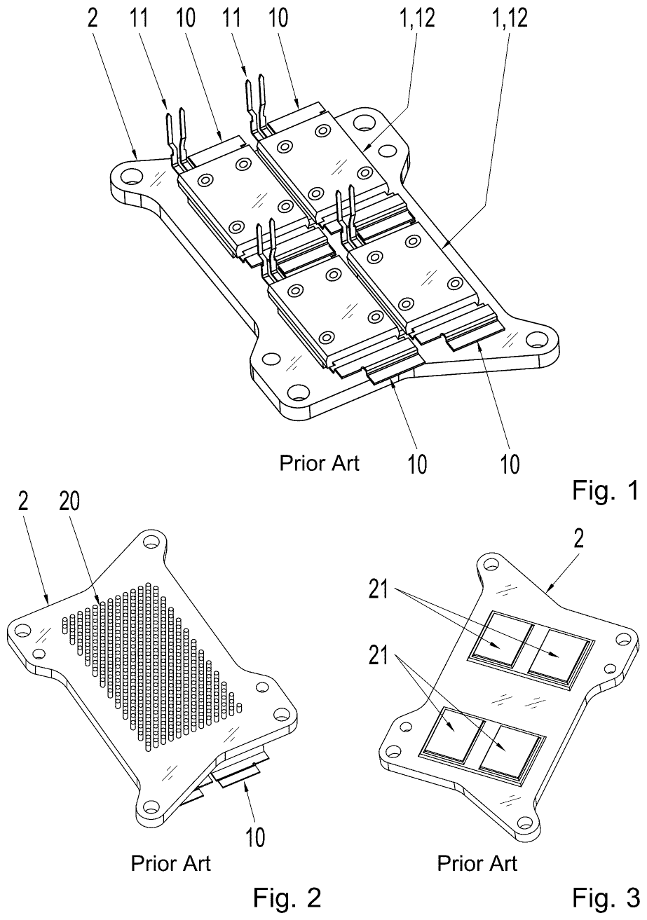

FIGS. 1 to 3 show a cooling assembly according to the prior art. FIG. 1 shows an assembly from above that has a substrate 2 populated with four power semiconductor modules 1. FIG. 2 shows the substrate 2 from below. This shows the cooling structure 20 on the bottom of the substrate 2 formed by pins. These effectively remove heat from a coolant flowing over the bottom of the substrate 2. FIG. 3 shows a substrate 2 from above that has sintered areas 21. In the prior art, the lower copper layer is attached to these sintered areas 21 in a sintering process. Consequently, the semiconductor switch is connected to the coolant by the substrate 2, which is made of a thermally conductive material.

The substrate 2 is made of metal, normally copper. The lower copper layer in the power semiconductor module 1 is sintered to this material, resulting in a permanent connection between the substrate 2 and the power semiconductor module 1. Furthermore, the heat generated by the semiconductor switches can be conducted into a coolant through the metal substrate 2. It is difficult to maintain the necessary tolerances for the power semiconductor module 1 during the sintering process, and this can result in subsequent delamination of the power semiconductor module 1. For this reason, another goal of the present disclosure is to eliminate the sintering process, without diminishing the necessary cooling of the semiconductor switch.

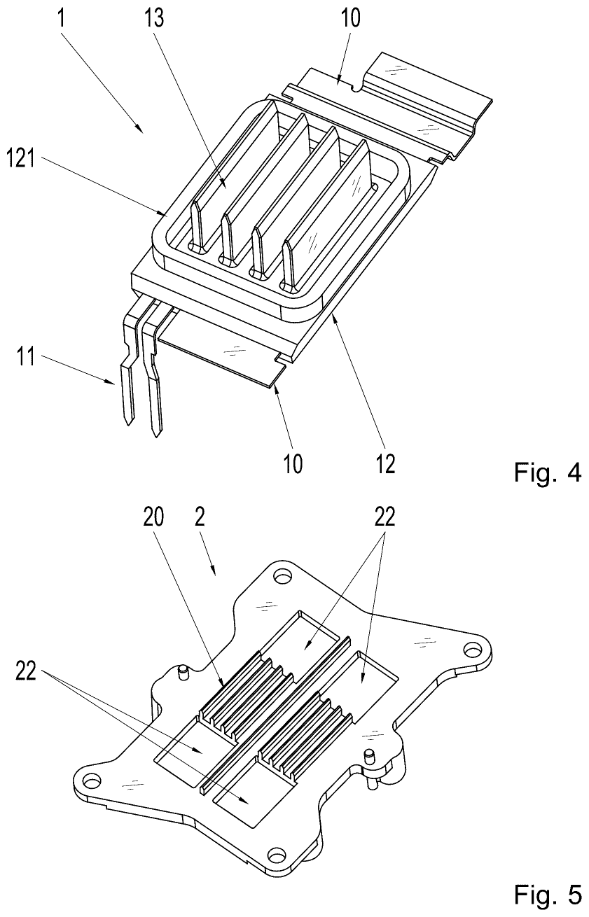

A cooling assembly for power semiconductor modules 1 is proposed in which the power semiconductor modules 1 have their own cooling structure that passes through the substrate 2 and is therefore in direct contact with coolant conducted along the bottom of the substrate 2. The cooling assembly shall be explained below in reference to FIGS. 4 to 9.

FIG. 4 shows the power semiconductor module 1 obtained with the present disclosure from below. Fundamentally, this power semiconductor module 1 is like that from the prior art. The difference is that the lower copper layer, connected to the substrate 2, forms a cooling structure 13. Furthermore, the part of the insulating layer 12 encompassing the cooling structure 12 forms a collar 121.

The cooling structure 13 is advantageously produced as part of the lower copper layer, i.e. as an integral part thereof. The cooling structure 13 can also be a separate structure, which is subsequently attached to the lower copper layer, ideally prior to attaching it to the semiconductor switch.

The cooling structure 13 is formed by fins in the embodiment shown in FIG. 4. It can also be formed by pins or some other structure. The important thing is that it provides a large surface area with which the heat generated by the semiconductor switches can be effectively discharged.

The substrate 2 obtained with the present disclosure is shown from below in FIG. 5. It has a cutout 22 where the sintering area 21 was previously located on the top, and a cooling structure was formed on the bottom (see FIG. 2). The cooling structure 13 on the respective power semiconductor module 1 passes through this cutout 22 when it is attached to the top of the substrate 2.

The substrate 2 can also have a cooling structure 20 on the bottom, where the cooling structures 13 of the power semiconductor modules 1 protrude, in particular below the electrical connections 10 for the power semiconductor modules 1. The cooling structure 20 can have the same form as the cooling structure 13 on the power semiconductor modules 1. It can also differ therefrom, if another form can optimize the coolant flow.

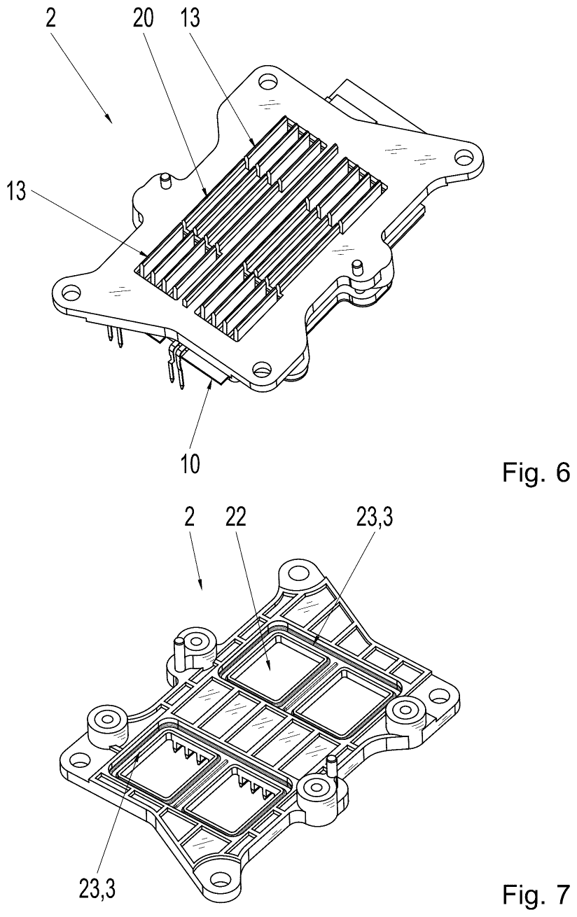

FIG. 6 shows a cooling assembly from below, i.e. a substrate 2 populated with power semiconductor modules 1, the cooling structures 13 on which pass through the cutouts 22 in the substrate 2.

FIG. 7 shows the top of the substrate 2. There are numerous cutouts 22 therein as well, each of which can accommodate a cooling structure 13 on a power semiconductor module 1.

In this embodiment, it can be seen that the cutouts 22 are surrounded by a recess 23 forming a moat. These recesses 23 correspond to the collars 121 formed on the power semiconductor modules 1, and help in the positioning thereof. The recess 23 also seals against the coolant flowing over the bottom of the substrate 2. It is also possible to attach the power semiconductor module 1 directly to the top of the substrate 2. In this case, the collar 121 is formed on the power semiconductor module 1, and bears on the substrate 2, such that it forms a seal (against the coolant). There can also be a separate seal that surrounds the collar 121 (sprayed thereon), preventing any coolant from reaching the top of the substrate 2.

In another embodiment (not shown), a seal can be simply placed in the recess 23. This requires a clamp (not shown) on top of the power semiconductor module 1, that presses the power semiconductor 1 against the seal. The clamp can be attached to the substrate or some other component in the electronic module.

Adhesive 3 is advantageously used as both a seal and to attach the power semiconductor module 1. If the substrate 2 has a recess 23, and the power semiconductor module 1 has a collar 121, adhesive 3 is placed in the recess 23 in a preferred embodiment, with which the power semiconductor module 1 is secured in the recess. The adhesive 3 also forms a seal (against coolant) in this case.

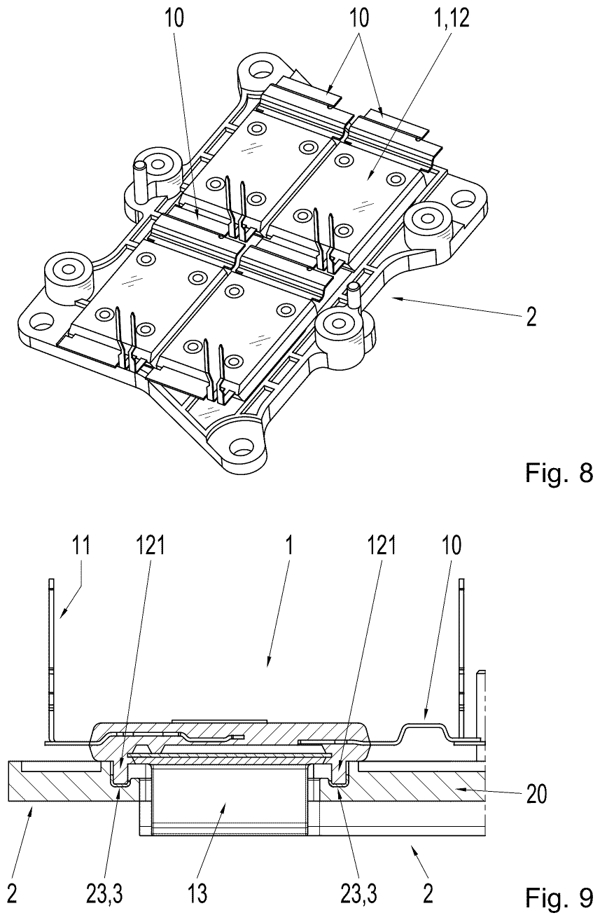

FIG. 8 shows the top of the cooling assembly obtained with the present disclosure, in which four power semiconductor modules 1 are place on a substrate 2. It is clear to the person skilled in the art that fewer or more power semiconductor modules 1 can be placed on a substrate, depending on the application.

FIG. 9 shows a sectional view through part of the cooling assembly obtained with the present disclosure, in a preferred embodiment. This shows how the collar 121 is placed in the recess 23 and secured in place there by adhesive 3. It also shows that the cooling structure 13 for the power semiconductor module 1 passes through the substrate 2 and extends from the bottom thereof. The cooling structure 20 on the substrate 2, shown in FIGS. 5 and 6, is on the right side, and is designed in one embodiment such that it is flush with the cooling structure 13 on the power semiconductor module 1. The cooling structure 20 on the substrate 1 can also be offset to the cooling structure 13 on the power semiconductor module 1. The depth of the recess 23 is such that it helps in positioning the power semiconductor module 1, and a seal can be placed therein, e.g. in the form of an adhesive 3 (preferred), or a separate seal. Consequently, the power semiconductor 1 can be reliably placed such that the collar 121 is sealed against the coolant. The collar 121 and recess 23 are designed such that they fit together with as little play as possible. If adhesive 3 is used, it fills the gap between the collar 121 and the recess 23, at least in part.

The substrate 2 in the cooling assembly obtained with the present disclosure can be made of metal, as in the prior art, in which case any clearances must be maintained. Ideally, the substrate 2 is made of a non-conductive material such as plastic. This results in a much lighter substrate 2 that can be produced in an injection molding process. This also eliminates the need for sintering, because the power semiconductor modules 1 are glued into the recesses 23 (or held in place by a clamp).

The proposed cooling assembly is advantageously used in an inverter in power electronics preferably used in an electric drive for a vehicle that has a three-phase electric motor and a battery. The power electronics has an inverter with numerous phases and is connected to an electric motor and batter to convert direct current from the battery into alternating current for the motor. The inverter is controlled by an electronic control unit (ECU) that is part of the power electronics. This ECU is connected to the electric motor and the inverter. The motor forms an electric axle drive.

A vehicle, e.g. a passenger automobile or utility vehicle ideally has such a drive. The vehicle is specifically a utility vehicle such as a truck or bus, or a passenger automobile. The power electronics module (i.e. the power electronics) comprises a DC/AC inverter such as that described above. It can also contain or be part of an AC/DC rectifier, DC/DC converter, transformer, and/or another type of converter, or part of such a converter. In particular, the power electronics module provides electricity to a motor and/or generator.

### LIST OF REFERENCE SYMBOLS

1 power semiconductor module
10 electrical connection
11 signal connection
12 insulating layer (mold)
121 collar
13 cooling structure
2 substrate
20 cooling structure
21 sintering area
22 cutout
23 recess
3 adhesive

1. A cooling assembly for a power semiconductor module, comprising:
a substrate; and
at least one power semiconductor module attached to the substrate,
wherein the at least one power semiconductor module has at least one semiconductor switch and are encased in an insulating compound, aside from at electrical connections, signal connections, and a cooling connection on a bottom of the power semiconductor module, and wherein the cooling connection forms a cooling structure extending from the bottom of the power semiconductor module, and
wherein the substrate comprises a cutout where the at least one power semiconductor module is attached, such that the cooling structure extends from a top of the substrate, where the power semiconductor module is, to a bottom of the substrate.

2. The cooling assembly according to claim 1,
wherein the insulating compound encompasses the cooling structure in a form of a collar extending from the bottom of the power semiconductor module, with which the power semiconductor module is attached to the substrate.

3. The cooling assembly according to claim 2,
wherein the top of the substrate comprises a recess in which the collar is placed.

4. The cooling assembly according to claim 3,
wherein adhesive is placed in the recess that secures the collar therein and forms a seal.

5. The cooling assembly according to claim 3,
wherein a seal is placed in the recess, and a clamp is placed on top of the power semiconductor module pressing it against the seal.

6. The cooling assembly according to claim 1,
wherein the cooling structure on the power semiconductor module is formed by fins or pins.

7. The cooling assembly according to claim 1,
wherein the substrate has a cooling structure on the bottom of the substrate corresponding to and extending the cooling structure on the power semiconductor module.

8. The cooling assembly according to claim 1,
wherein the substrate is made of metal or plastic.

9. Power electronics for operating a three-phase electric motor in a vehicle, comprising:
an inverter formed by the at least one power semiconductor module;
the cooling assembly according to claim 1; and
at least one electronic control unit connected to the motor and the inverter.

10. A power semiconductor module comprising:
at least one semiconductor switch,
wherein the power semiconductor module is encased in an insulating compound, aside from at electrical connections, signal connections, and a cooling connection on a bottom of the power semiconductor module, and
wherein the cooling connection forms a cooling structure extending from the bottom of the power semiconductor module.

11. The power semiconductor module according to claim 10,
wherein the insulating compound encompasses the cooling structure in a form of a collar extending from the bottom of the power semiconductor module.
